(19) United States
(12) Patent Application Publication
(10) Pub. No.: US 2025/0113664 A1
(43) Pub. Date: Apr. 3, 2025

(54) LIGHT-EMITTING DEVICES EXCITED BY IMPACT IONIZATION

(71) Applicant: Ohio University, Athens, OH (US)

(72) Inventor: Faiz Rahman, Athens, OH (US)

(21) Appl. No.: 18/729,570

(22) PCT Filed: Jan. 13, 2023
(86) PCT No.: PCT/US2023/010741

§ 371 Date: Jul. 17, 2024

Related U.S. Application Data
(60) Provisional application No. 63/300,094, filed on Jan. 17, 2022.

(51) Int. Cl. H10H 20/821; H10H 20/01; H10H 20/816; H10H 20/831; H10H 20/833; H10H 20/85

(52) U.S. Cl. CPC H10H 20/821; H10H 20/032; H10H 20/816; H10H 20/831; H10H 20/833; H10H 20/8508

(57) ABSTRACT

Light-emitting devices and methods for making light-emitting devices. A light-emitting device includes a high-field electrode, a collector electrode, and a light generating region. The collector electrode is operatively coupled to one side of the light generating region, and the high-field electrode is operatively coupled to another side of the light generating region opposite the collector electrode. The high-field electrode includes protruding electrode elements that extend into the light generating region and toward the collector electrode. The protruding electrode elements accelerate carriers in the light generating region in response to a voltage being applied between the high-field electrode and the collector electrode. The carriers have sufficient kinetic energy to create electron-hole pairs in the light generating region through impact ionization. When these electron-hole pairs recombine, at least a portion of the recombination events emit a photon with an energy corresponding to the bandgap of the light generating region.

### CROSS-REFERENCE TO RELATED APPLICATIONS

The present application is a National Phase Entry submitted under 35 U.S.C. § 371 of International Application No. PCT/US2023/010741, filed Jan. 13, 2023, which claims the filing benefit of U.S. Provisional Application Ser. No. 63/300,094, filed Jan. 17, 2022, the disclosures of which are incorporated by reference in their entireties.

### BACKGROUND

The present invention generally relates to light-emitting devices and, in particular, to solid state light-emitting devices, and methods of fabricating light-emitting devices, that are excited by emitting electrons (field emission) and/or accelerating electrons into a semiconductor using a high electric field electrode, hereinafter referred to as high field electrode.

Light-emitting devices that operate in the ultra-violet (UV) region have many applications, such as air and water sterilization, surface disinfection, lithography, and materials processing (e.g., industrial resin curing), to name a few. Wide bandgap semiconductors would appear at first glance to be a preferred choice for making the next generation of short wavelength light-emitting devices. However, persistent problems with p-type doping of wide bandgap semiconductors have prevented device makers from realizing the potential of these materials. Despite much global effort over the past several decades, there has been little progress in developing high-quality p-type wide bandgap semiconductors.

A commonly used semiconductor in light-emitting diodes (LEDs) is gallium nitride (GaN), which has a bandgap of about 3.4 eV. The bandgap of GaN can be adjusted upward by substituting aluminum for at least a part of the gallium (AlₓGaₓ₋₁N), and downward by substituting indium for at least a part of the gallium (InₓGaₓ₋₁N). However, beyond certain values of x, adding aluminum or indium to GaN typically results in element segregation and a corresponding deterioration of material properties in the form of aluminum or indium rich regions and increased dislocation density. These defects in the material lead to inefficient emission of light due to excessive non-radiative recombination of electron-hole pairs, which generates heat rather than photons.

Another problem with wide bandgap semiconductors is that wider bandgaps lead to less efficient hole generation with acceptor dopants. This is mainly due to the wider forbidden energy gap, which causes acceptor levels to be farther away from the valence band edge. As a result, acceptor atoms require more thermal energy to ionize, which leads to fewer ionized acceptors and correspondingly fewer holes in the valence band. These two effects impose inherent limitations on the efficiency of light emission from wide bandgap semiconductors that rely on p-n junctions.

Thus, both the physics (higher acceptor ionization energies) and, in at least some cases, materials science (phase segregation) of wide bandgap materials currently limit their performance. Due to these intrinsic problems with wide bandgap materials, available AlGaN-based deep UV LEDs are very inefficient, e.g., ˜4% wall plug efficiency for commercial devices emitting below 300 nm. For example, a model CSU334 280 nm peak wavelength deep UV LED available from the Nichia Corporation of Anan Japan, operating at forward voltage of 5 volts and a forward current of 350 mA, produces only 55 mW of optical output power. This represents an operating electrical-to-UV light conversion efficiency of just above 3%. Devices emitting light at wavelengths below 250 nm have even poorer conversion efficiencies of 1% or less. Thus, while low power near-UV LEDs are available, these devices are not efficient enough for many applications where they could otherwise be usefully employed.

The lack of efficient high-power UV LEDs represents an unmet need for energy-efficient solid-state light sources in the UV region of the electromagnetic spectrum. Moreover, because making p-n junction diode-based light emitters from wide bandgap semiconductors becomes increasingly more difficult as their bandgap increases, the above problems with conventional solid-state UV emitting devices only become more difficult to solve for short wavelength devices.

Thus, there is a general need for improved solid state light-emitting devices, and in particular, there is a need for improved wide-bandgap solid state light-emitting devices that emit light in the UV and near-UV regions.

### SUMMARY

In an aspect of the disclosure, a light-emitting device is disclosed. Depending on the energy band gap of the semiconductor employed, the light emission may be in the visible or invisible region of the electromagnetic spectrum. The latter may be infrared or ultraviolet radiation. The light-emitting device includes a high field electrode with at least one protruding electrode element, a collector electrode, and a light generating region located between the high field electrode and the collector electrode. The protruding electrode element extends into the light generating region and accelerates carriers in the light generating region in response to a voltage applied between the high field electrode and the collector electrode.

In an embodiment of the disclosed light-emitting device, the protruding electrode element may be configured to inject carriers into the light generating region.

In another embodiment of the disclosed light-emitting device, the light generating region may be formed from a direct bandgap semiconductor.

In another embodiment of the disclosed light-emitting device, the direct bandgap semiconductor may include at least one of AlN, GaN, AlGaN, InGaN, InAlN, InGaAlN, BN, Ga₂O₃, ZnO, AlZnO, MgZnO, and MgBeZnO.

In another embodiment of the disclosed light-emitting device, the high field electrode may include a field emission layer configured to inject electrons into the light generating region.

In another embodiment of the disclosed light-emitting device, the field emission layer may include at least one of calcium, lithium, or magnesium.

In another embodiment of the disclosed light-emitting device, the light-emitting device may further include a transparent substrate on which the collector electrode is formed.

In another embodiment of the disclosed light-emitting device, the transparent substrate may be made from one or more of sapphire, fused silica, ZnO, GaN, or SiC.

In another embodiment of the disclosed light-emitting device, the collector electrode may include at least one of Al, Ga doped ZnO, indium tin oxide (ITO), or bi-metallic Ni/Au.

In another embodiment of the disclosed light-emitting device, the at least one protruding electrode element may include a base attached to the high field electrode, and a tip opposite the base from which a majority of the carriers are injected and/or accelerated into the light generating region.

In another embodiment of the disclosed light-emitting device, the at least one protruding electrode element may include a tapered region between the base and the tip such that the tip is narrower than the base.

In another aspect of the disclosure, a method of making the light-emitting device is disclosed. The method includes forming the light generating region having a first side and a second side opposite the first side, forming the high field electrode with the at least one electrode element that extends into the first side of the light generating region, and forming the collector electrode on the second side of the light generating region such that the light generating region is located between the high field electrode and the collector electrode. The protruding electrode element is configured to accelerate carriers in the light generating region in response to the voltage being applied between the high field electrode and the collector electrode.

In an embodiment of the method, the at least one protruding electrode element may be configured to inject carriers into the light generating region.

In another embodiment of the method, forming the light generating region may include depositing the direct bandgap semiconductor onto one of the collector electrode or the high field electrode.

In another embodiment of the method, the direct bandgap semiconductor may include at least one of AlN, GaN, AlGaN, InGaN, InAlN, InGaAlN, BN, Ga₂O₃, ZnO, AlZnO, MgZnO, and MgBeZnO.

In another embodiment of the method, forming the high field electrode may include depositing the field emission layer that is configured to inject electrons into the light generating region onto the first side of the light generating region.

In another embodiment of the method, depositing the field emission layer may include depositing at least one of calcium, lithium, or magnesium.

In another embodiment of the method, forming the anode may include depositing the conductive layer on the transparent substrate.

In another embodiment of the method, the transparent substrate may include sapphire, fused silica, ZnO, GaN, or SiC.

In another embodiment of the method, the conductive layer may include depositing at least one of Al, Ga doped ZnO, indium tin oxide (ITO), or bi-metallic Ni/Au.

In another embodiment of the method, the at least one protruding electrode element may include the base attached to the high field electrode, and the tip opposite the base from which the majority of the carriers are injected and/or accelerated into the light generating region.

In another embodiment of the method, the at least one protruding electrode element may include the tapered region between the base and the tip such that the tip is narrower than the base.

### BRIEF DESCRIPTION OF THE DRAWINGS

The accompanying drawings, which are incorporated in, and constitute a part of this specification, illustrate various embodiments of the invention and, together with the general description of the invention given above, and the detailed description of the embodiments given below, serve to explain the embodiments of the invention.

FIG. 1 is a diagrammatic cross-sectional view of an exemplary light-emitting device including a light-emitting region and a plurality of electrode elements extending into the light-emitting region.

FIG. 2 is a partially transparent perspective view of an embodiment of the exemplary light-emitting region of FIG. 1 showing the electrode elements arranged in a two-dimensional array.

FIG. 3 is a perspective view of an exemplary light-emitting region including features configured to define the two-dimensional array of electrode elements prior to formation thereof.

FIG. 4 is a perspective view of the two-dimensional array of electrode elements of FIG. 3.

FIG. 5 is a graphical view of cathodoluminescence intensity verses wavelength for an exemplary material that may be used to form the light-emitting region of FIG. 1.

### DETAILED DESCRIPTION

Embodiments of the invention include light-emitting devices in which impact ionization is used to generate electron-hole pairs in a semiconductor material. In response, the semiconductor emits electromagnetic radiation (e.g., visible or ultraviolet (UV) light) through radiative recombination of the electron-hole pairs. Impact ionization is a process by which one charge carrier loses energy through the generation of additional charge carriers. In a semiconductor, a charge carrier (e.g., an electron) having sufficient energy may excite an electron from the valence band into the conduction band, thereby creating an electron-hole pair. Sufficient kinetic energy to create electron-hole pairs in a semiconductor through impact ionization may be provided using a sufficiently high electric field. If an energetic charge carrier creates an electron-hole pair in the region of this high electrical field, it may result in an avalanche breakdown that produces a large number of electron-hole pairs. When these electron-hole pairs recombine in the semiconductor, at least a portion of them emit photons with an energy corresponding to the bandgap of the semiconductor.

A light-emitting diode (LED) has a p-n junction that relies on a shaped potential profile of the band edges to inject electrons and holes into an active layer of the LED. Impact ionization is an entirely different way of exciting emissions in semiconductors that avoids the need for p-n junctions. Advantageously, because p-n junctions are not used to inject the electron-hole pairs into the semiconductor, light-emitting devices that rely on impact ionization do not need p-type doped semiconductors. This is particularly advantageous when using wide bandgap semiconductors capable of emitting ultraviolet light, such as ZnO, MgZnO, and AlGaN, due to difficulties in doping these materials as p-type semiconductors.

The disclosed light-emitting devices include a high-field electrode for generating a high electric field in the light-emitting semiconductor. The high electric field serves to accelerate electrons for the purpose of impact ionization. The same electrode can also serve the dual purpose of injecting electrons through field emission in semiconductors that do not possess a large enough population of intrinsic electrons. The high-field electrode has one or more protruding electrode elements that extend into the light generating region of the device, which is formed from a suitable semiconductive material. These electrode elements may be arranged in a two-dimensional array, include a sharply pointed tip, and may be coated with a low work function material. The high-field electrode may thereby be configured to inject streams of electrons directly into the light generating region of the device in cases where the intrinsic carrier density of the light generating semiconductor is less than optimal.

The injected carriers, the intrinsic carriers intrinsically present in the semiconductor, or both the injected and intrinsic carriers, may be accelerated by an electric field generated by the high-field electrode and cause further electron-hole pair generation from impact ionization. Avalanche multiplication of electron-hole pairs in the light generating region may further increase the number of carriers. The electron-hole pairs may then undergo radiative recombination, thereby producing electromagnetic radiation having wavelengths consistent with the bandgap of the semiconductor material. Advantageously, the above described device structure is not specifically tied to any particular semiconductor material, and can, therefore, be adapted to different semiconductors having different bandgaps. Thus, desirable properties of different wide bandgap semiconductors may be leveraged to make devices optimized for different applications without concern for their ability to be doped as either a p-type or n-type semiconductor.

For instance, MgZnO and AlGaN may be utilized for making deep UV light-emitting devices, whereas ZnO may be used to make light-emitting devices that emit in the blue, violet, and near-UV regions. Certain semiconductors (e.g., ZnO, MgZnO) may intrinsically contain a significant number of free electrons due to the inevitable presence of natural defects. Other semiconductors (e.g., AlGaN and AlN) may not intrinsically contain a significant number of free electrons. In the latter case, the light-emitting devices may depend on the electrode elements to inject electrons into the semiconductor. In the case of ZnO family semiconductors, electron injection may not be needed as a sufficient concentration of free electrons is typically available in the material. In either case, the electrons (natural or injected) are accelerated to high velocities by the electric field. Thus, one function of the electrode elements, regardless of semiconductor type, may be to create an electric field that accelerates carriers in the light-emitting region. Electrode elements having a pointed shape may lower the voltage necessary to create a sufficiently high electric field. In the case of semiconductors lacking sufficient free electrons (e.g., nitride based semiconductors), pointy electrode elements may also act as field emitters that inject electrons into the light-emitting region.

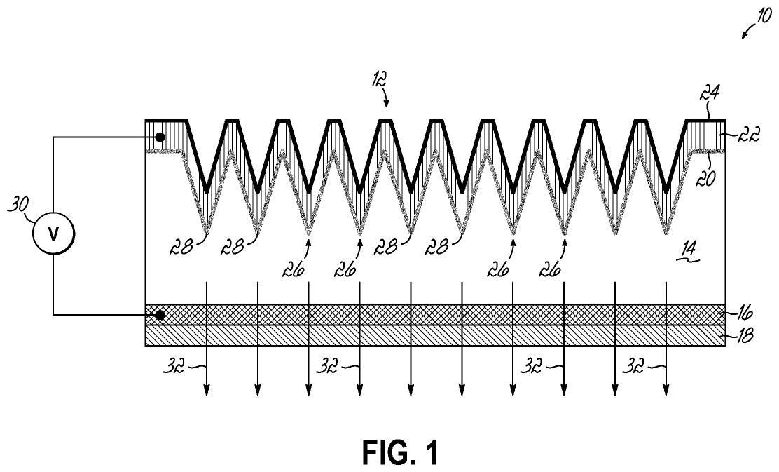

FIG. 1 depicts a cross-sectional diagrammatic view of an exemplary light-emitting device 10 in accordance with an embodiment of the invention. The light-emitting device 10 includes a high-field electrode 12 (e.g., that serves as a cathode), a light generating region 14, a collector electrode 16 (e.g., that serves as an anode), and a substrate 18. The high-field electrode 12 may include an electron emitter layer 20, a diffusion barrier layer 22, and a sealant layer 24. The electron emitter layer 20 may include a layer of conductive material (i.e., a conductive layer) having a low work function, such as calcium (Ca), to promote field emission of electrons into the light generating region 14. Desirable properties of the field emission layer material may include, in addition to the low work function, a high reflectivity in the spectral region of the light emitted by the light generating region 14. The diffusion barrier layer 22 may be formed from a refractory metal, such as titanium (Ti), and the sealant layer 24 may be formed from a chemically inactive conductor, such as gold (Au). The thicknesses of these layers may be selected to control the parasitic resistance of the light-emitting device 10.

The high field electrode 12 may include a plurality of protruding electrode elements 26 that extend into the light generating region 14. Each electrode element 26 may have a columnar, conical, frustoconical, pyramidal, or other shape that forms a sharply pointed apex, or tip 28. Such pointed electrode elements serve to enhance the magnitude of the electric field in their vicinity. Each tip 28 may be connected to a base of the element by a tapered region such that the tips 28 resemble a sphere on orthogonal cone (SOC) with a radius of between 1 and 100 nm. Exemplary dimensions of the electrode elements 26 may include a width at their respective bases of 100 to 1500 nm, a spacing of 200 to 3000 nm (tip to tip), and an extension of 100 to 1500 nm (tip to base) into the light generating region 14.

Application of a voltage 30 between the high-field electrode 12 and the collector electrode 16 may cause charge carriers (e.g., electrons) to be emitted from the electrode elements 26. These carriers may be concentrated in regions proximate to the tips 28 of the electrode elements 26, and may transfer sufficient energy to valance band electrons in the light generating region 14 to excite electrons into the conduction band, thereby forming electron-hole pairs. Some of these conduction band electrons may be accelerated by the electric field between the emission and collector electrodes to sufficient energy levels to create further electron-hole pairs. At least a portion of the resulting electron-hole pairs may radiatively recombine to produce light 32 having a wavelength proportional to the bandgap of the semiconductor material forming the light generating region 14. At least a portion of the light 32 may be radiated out of the light-emitting device 10 through the collector electrode 16 and substrate 18.

The light generating region 14 may be located between the high field electrode 12 and the collector electrode 16 and fill in the space between electrode elements 26. Suitable materials for forming the light generating region 14 may include direct bandgap semiconductors, such as II-oxides (e.g., ZnO and related materials) and III-nitrides (e.g., GaN and related materials). Materials used to form the light generating region 14 may be selected to have band gaps that produce a desired wavelength of light to be emitted by the light-emitting device 10, and for other characteristics such as lattice constant and index of refraction. The collector electrode 16 may be formed from any conductive material that is fully or partially transparent to the light emitted by the light generating region. Exemplary materials that may be used to form the collector electrode 16 include Al or Ga doped ZnO (e.g., Al:ZnO or AZO), Indium Tin Oxide (IOT), thin bi-metallic layers (e.g., Ni/Au) or any other suitable transparent or semi-transparent conductive material.

The substrate 18 may be a transparent substrate formed from sapphire (Al₂O₃), silica (SiO₂), bulk polished ZnO, GaN, or SiC wafers, or any other suitable material compatible with the conductive and semiconductive materials used to form the light-emitting device 10. The substrate 18 may also include one or more buffer layers (not shown), such as an epitaxially deposited GaN layer. When present, the buffer layer may provide a buffer against lattice mismatches between the substrate 18 and collector electrode 16. The substrate 18 may also be configured to act as an optical impedance matching layer between the collector electrode 16 and external environment (e.g., air) that enhances light extraction from the light generating region 14. By way of example, for a light-emitting device formed from a ZnO-based material (refractive index ˜2.05), a fused silica substrate (refractive index ˜1.46) having a thickness of about 35 nm could be used to reduce the effects of the refractive index discontinuity between ZnO and air for UV light having a wavelength of about 200 nm.

The light-emitting device 10 may be fabricated using known methods of semiconductor processing. By way of example, a layer of AZO may be deposited onto a bulk sapphire substrate to form the collector electrode 16. AZO films may be deposited by a variety of methods, such as sol-gel techniques, pulsed laser deposition, atomic layer deposition (ALD), and radio frequency (RF) magnetron sputtering. A layer of ZnO may then be epitaxially grown on the collector electrode 16 to provide the light generating region 14 using metal organic chemical vapor deposition (MOCVD), molecular beam epitaxy (MBE), ALD, or any other suitable technique.

The light generating region 14 may be selectively etched to define features into which the electrode elements 26 can be deposited. Semiconductor materials may be selectively etched through standard lithographic patterning followed by wet or dry chemical etching processes. Sub-micron features may be etched using acidic etchants, such as dilute orthophosphoric acid, containing appropriate surfactants. Ferric chloride and oxalic acid also work well for etching ZnO, for example. Examples of dry etching processes include inductively coupled plasma (ICP) dry etching of high-quality bulk single-crystal ZnO samples with both CH₄/H₂/Ar and Cl₂/Ar plasmas. After appropriately shaped structures have been etched into the light generating region 14, the electrode elements 26 may be formed by sequentially depositing the electron emitter layer 20, diffusion barrier layer 22, and non-reactive sealant layer 24, e.g., using evaporative or physical vapor deposition.

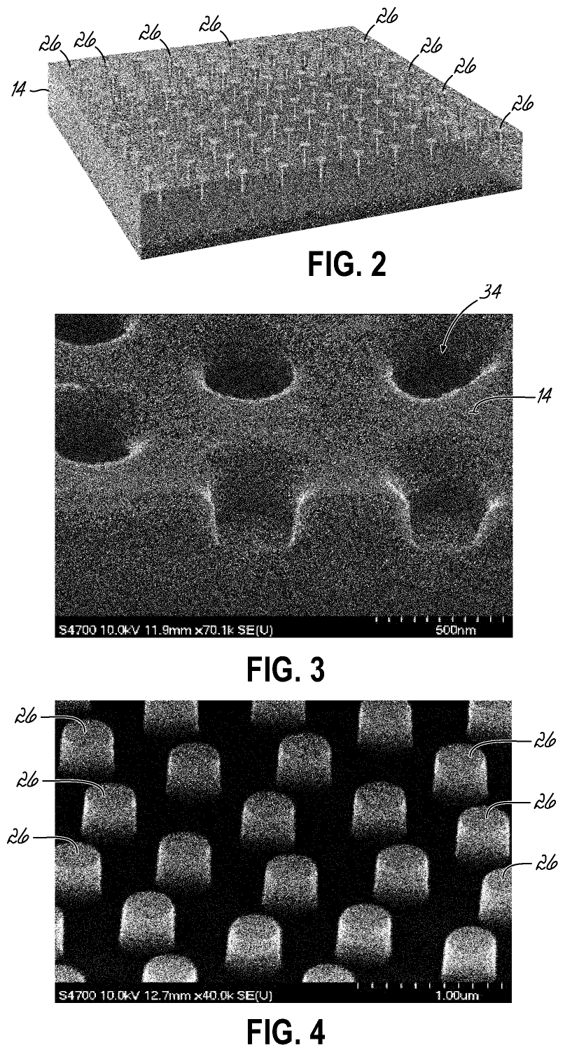

FIG. 2 depicts an exemplary light generating region 14 as a partially transparent layer in which a plurality of electrode elements 26 have been defined. The exemplary electrode elements 26 are arranged to form a two-dimensional array, however it should be understood that other arrangements may be used. FIG. 3 depicts a magnified image showing a perspective view of an exemplary light generating region 14 prior to formation of the electrode elements 26. A two-dimensional array of voids 34 has been defined in the light generating region 14, e.g., by selectively etching a layer of the material from which the light generating region 14 is formed. Each of the voids 34 may have a cylindrical or conical shape suitable for the electrode elements 26. FIG. 4 depicts a magnified image showing a perspective view of the electrode elements 26, which may be defined by filling the voids 34 with a conductive material. The voids 34 may be filled, for example, by depositing one or more layers of conductive material (e.g., a suitable metal or alloy), optionally followed by or including one or more planarizing steps.

The use of accelerated carriers to excite radiation from the light generating region 14 may be generally applicable to direct bandgap semiconductors. However, the use of accelerated carriers may be particularly advantageous with wide bandgap semiconductors due to problems with doping these types of semiconductors. This wide applicability may enable the properties of various wide bandgap semiconductors to be leveraged to make suitable devices for different applications. For instance, MgZnO and AlGaN may be preferred for making deep UV emitters, whereas ZnO may be preferred for making near-UV devices and, by extension, visible light emitters, with the use of suitable phosphors, such as YAG:Ce. Light-emitting devices may also use semiconductors doped with luminescent ions (such as Europium ions) to make narrowband visible light emitters. Additional wide bandgap semiconductors that may be used to form the light generating region 14 of light-emitting device 10 may include, but are not limited to, boron nitride (BN) and gallium oxide (Ga₂O₃).

The material-independence provided by using field emission to inject carriers into the light generating material may enable the production of light-emitting devices that serve a wide range of applications which touch on every field where UV light can be used. These light-emitting devices may have higher efficiencies as compared to deep-UV LEDs using similar materials, e.g., AlGaN epilayers.

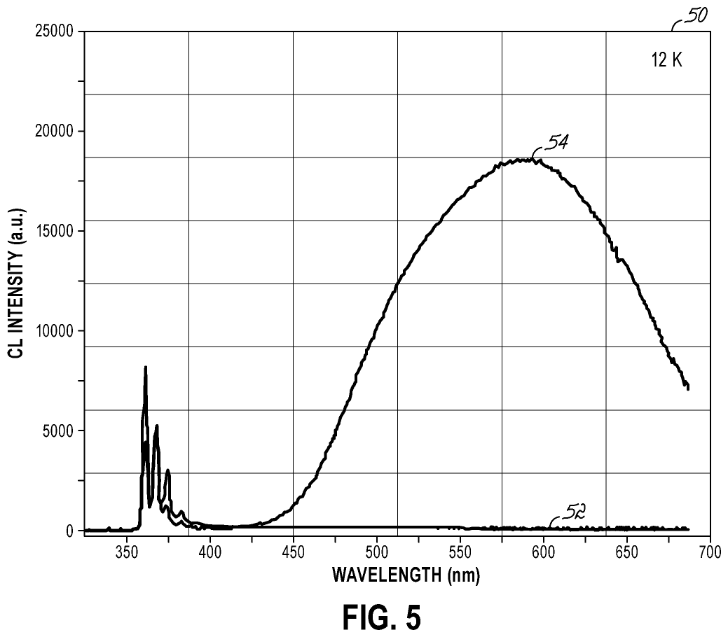

The advantages of field-emission carrier injection are not limited to light-emitting devices that operate in the UV range. FIG. 5 depicts a graph 50 of a cathodoluminescence intensity verses wavelength that includes a vertical axis indicating the cathodoluminescence (CL) intensity in arbitrary units (a.u.), and a horizontal axis indicating wavelength of the light in nm. The graph 50 further includes a plot 52 of emissions for a ZnO film grown on a sapphire substrate using MOCVD, and a plot 54 of emissions for hydrothermally grown bulk ZnO. The plots 52, 54 show near-UV emissions in the 360 to 380 nm range from each material when bombarded by a 5 keV free-space electron beam. These emissions provide an indication of the potential for near-UV light emission from devices based on ZnO. In addition to the emissions in the near-UV range, the plot 54 of bulk ZnO material depicts broad emissions in the visible light range of about 475-675 nm. These emissions are believed to be due to defects in the material, and may advantageously add to the visible light emitted by devices that use the near-UV emissions to excite a phosphor.

ZnO is readily available as both epitaxially grown films and hydrothermally grown bulk wafers, and may be cheaper and have a reduced environmental impact as compared to many other wide bandgap semiconductors. The near-UV light emitted by ZnO based devices may be converted to longer wavelength visible light using phosphors in a similar manner as in white-light LEDs in which a blue emitting LED is used to excite a phosphor. Thus, ZnO (and other semiconductors with similar bandgaps) may be used to generate blue, violet, or near-UV light that can be easily converted to white light for illumination purposes. The near-UV light in the 360 to 380 nm range emitted by ZnO-based impact ionization devices can be converted to almost any visible color (including broadband white) by the use of suitable phosphors. Advantageously, pumping phosphors with near-UV light may enable generation of a wider palette of visible colors than lower energy blue light sources. This wider palette of colors may enable customization of spectral profiles to suit different application requirements, such as object illumination, space illumination, horticulture, image projection, etc.

A ZnO-based light-emitting device excited by impact excitation-generated carriers may be significantly more energy efficient than devices which use InGaN/GaN-based blue LEDs to pump visible light-emitting phosphors. This increased efficiency may be due, at least, in part to the higher exciton binding energy of ZnO (˜60 meV) as compared to GaN (˜26 meV). Higher exciton binding energy may increase the likelihood of radiative electron-hole recombination, resulting in a higher photon flux as compared to materials having relatively low exciton binding energies.

Light trapping can also cause a substantial loss of efficiency with InGaN/GaN LEDs. Advantageously, because ZnO has 16% lower refractive index than GaN (2.15 versus 2.56 at 400 nm), use of ZnO may reduce light trapping within the confines of a ZnO emitter due to reduced internal reflection. Including a periodic array of spikes in the high-field electrode 12 may cause further efficiency gains by extracting any trapped light through scattering caused by the electron injecting structure itself. These spikes may be provided by the electrode elements 26, for example. ZnO-based and phosphor converted visible light-emitting devices may, therefore, have higher efficiency and greater brightness than their III-nitride LED counterparts. Embodiments of the invention may, thereby, provide improved performance and energy efficiency as compared to InGaN/GaN LEDs.

The use of wide bandgap semiconductor materials enables solid-state devices to emit light in the UV region through recombination of electron-hole pairs. Generating wavelengths below 400 nm through radiative recombination of electron-hole pairs requires the use of a semiconductor with a bandgap greater than 3.1 eV. A variety of semiconductors satisfy this requirement, many of which are compound semiconductors. GaN and various combinations of GaN with indium and aluminum are one family of semiconductors that may be used for both visible light and UV light-emitting devices. For example, GaN—InGaN quantum wells may be used to form green, blue, violet and UV-emitting devices. Increasing the indium content in the InGaN material may reduce the bandgap of the material forming the quantum wells, thereby lengthening the wavelength of the light emitted by the quantum well regions. Conversely, decreasing the indium content (or adding aluminum) widens the bandgap of the material, thereby causing the quantum wells to emit shorter wavelength radiation.

Besides the group III-nitride semiconductors (e.g, AlN, GaN, AlGaN, InGaN, InAlN, and InGaAlN), there are also other compound semiconductors that have suitably wide bandgaps for fabricating deep UV emission devices. For example, there are several compound semiconductors in the zinc oxide family, such as ZnO, MgZnO and MgBeZnO. ZnO itself has a direct bandgap of 3.3 eV, making it capable of emitting radiation in the near-UV region. The addition of magnesium widens the bandgap even further so that deeper UV emission wavelengths become possible.

An advantage of MgZnO as a wide bandgap material is that it does not suffer from phase segregation problems that plague high Al-content AlGaN alloys. Thus, it may be easier to target different emission wavelengths with MgZnO by adjusting magnesium content as compared to adjusting the aluminum content of GaN based devices. As noted above, the high exciton binding energy of ZnO makes it a potentially brighter radiation emitter when compared with GaN/InGaN based devices. Impact-ionization ZnO devices, doped with rare-earth ions or coated with phosphors, may have both higher brightness and efficiencies than GaN/InGaN based devices. Advantageously, this could significantly lower the amount of energy consumed by both indoor and outdoor illumination, thereby helping the environment through reductions in the demand for electrical energy.

The advantages of field-emission and non-field-emission impact-ionization devices as compared to their LED-based counterparts include avoiding the need for p-type doping of the semiconductor material from which the device is made. This advantage may allow the production of solid-state devices that generate deep-UV light with higher efficiency and at shorter wavelengths than is possible with devices that inject carriers using p-n junctions, thus making high luminous efficacy (lumens/watt) visible light emitters available for general purpose illumination applications.

The terminology used herein is for the purpose of describing particular embodiments only, and is not intended to be limiting of the embodiments of the invention. As used herein, the singular forms “a”, “an” and “the” are intended to include both the singular and plural forms, and the term “or” is intended to include both alternative and conjunctive combinations, unless the context clearly indicates otherwise. It will be further understood that the terms “comprises” or “comprising,” when used in this specification, specify the presence of stated features, integers, actions, steps, operations, elements, or components, but do not preclude the presence or addition of one or more other features, integers, actions, steps, operations, elements, components, or groups thereof. Furthermore, to the extent that the terms “includes”, “having”, “has”, “with”, “comprised of”, or variants thereof are used in either the detailed description or the claims, such terms are intended to be inclusive in a manner similar to the term “comprising”.

It should also be understood that the drawings are not necessarily to scale, and may present a somewhat simplified representation of various features illustrative of the basic principles of the invention. The specific design features of the sequence of operations as disclosed herein, including, for example, specific dimensions, orientations, locations, and shapes of various illustrated components, may be determined in part by the particular intended application and use environment. In particular, certain features and dimensions of the illustrated embodiments may have been enlarged or distorted relative to others to facilitate visualization and a clear understanding.

While all the invention has been illustrated by a description of various embodiments, and while these embodiments have been described in considerable detail, it is not the intention of the Applicant to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the spirit or scope of the Applicant's general inventive concept.

What is claimed is:

1. A light-emitting device comprising:
a high-field electrode with at least one protruding electrode element;
a collector electrode; and
a light generating region located between the high-field electrode and the collector electrode,
wherein the at least one protruding electrode element extends into the light generating region, and the at least one protruding electrode element is configured to accelerate carriers in the light generating region in response to a voltage being applied between the high-field electrode and the collector electrode.

2. The light-emitting device of claim 1, wherein the at least one protruding electrode element is configured to inject carriers into the light generating region.

3. The light-emitting device of claim 1, wherein the light generating region is formed from a direct bandgap semiconductor.

4. The light-emitting device of claim 3, wherein the direct bandgap semiconductor includes at least one of AlN, GaN, AlGaN, InGaN, InAlN, InGaAlN, BN, Ga₂O₃, ZnO, AlZnO, MgZnO, and MgBeZnO.

5. The light-emitting device of claim 1, wherein the high field electrode includes a field emission layer configured to inject electrons into the light generating region.

6. The light-emitting device of claim 5, wherein the field emission layer includes at least one of calcium, lithium, or magnesium.

7. The light-emitting device of claim 1, further comprising a transparent substrate on which the collector electrode is formed.

8. The light-emitting device of claim 7, wherein the transparent substrate is made from one or more of sapphire, fused silica, ZnO, GaN, or SiC.

9. The light-emitting device of claim 1, wherein the collector electrode includes at least one of Al, Ga doped ZnO, indium tin oxide (ITO), or bi-metallic Ni/Au.

10. The light-emitting device of claim 1, wherein the at least one protruding electrode element includes a base attached to the high field electrode, and a tip opposite the base from which a majority of the carriers are injected and/or accelerated into the light generating region.

11. The light-emitting device of claim 10, wherein the at least one protruding electrode element includes a tapered region between the base and the tip such that the tip is narrower than the base.

12. A method of making a light-emitting device, comprising:
forming a light generating region having a first side and a second side opposite the first side;
forming a high-field electrode with at least one electrode element that extends into the first side of the light generating region; and
forming a collector electrode on the second side of the light generating region such that the light generating region is located between the high-field electrode and the collector electrode,
wherein the at least one protruding electrode element is configured to accelerate carriers in the light generating region in response to a voltage being applied between the high-field electrode and the collector electrode.

13. The method of claim 12, wherein the at least one protruding electrode element is configured to inject carriers into the light generating region.

14. The method of claim 12, wherein forming the light generating region includes depositing a direct bandgap semiconductor onto one of the high-field electrode or the collector electrode.

15. The method of claim 14, wherein the direct bandgap semiconductor includes at least one of AlN, GaN, AlGaN, InGaN, InAlN, InGaAlN, BN, Ga₂O₃, ZnO, AlZnO, MgZnO, and MgBeZnO.

16. The method of claim 12, wherein forming the high-field electrode includes depositing a field emission layer onto the first side of the light generating region, and the field emission layer is configured to inject electrons into the light generating region.

17. The method of claim 16, wherein depositing the field emission layer includes depositing at least one of calcium, lithium, or magnesium.

18. The method of claim 12, wherein forming the anode includes depositing a conductive layer on a transparent substrate.

19. The method of claim 18, wherein the transparent substrate includes sapphire, fused silica, ZnO, GaN, or SiC.

20. The method of claim 18, wherein depositing the conductive layer includes depositing at least one of Al, Ga doped ZnO, indium tin oxide (ITO), or bi-metallic Ni/Au.

21. The method of 12, wherein the at least one protruding electrode element includes a base attached to the high-field electrode, and a tip opposite the base from which a majority of the carriers are injected and/or accelerated into the light generating region.

22. The method of claim 21, wherein the at least one protruding electrode element includes a tapered region between the base and the tip such that the tip is narrower than the base.
